(19) United States
(12) Patent Application Publication
(10) Pub. No.: US 2015/0198652 A1
(43) Pub. Date: Jul. 16, 2015

(54) Method and device for insulation monitoring including alarm diagnosis display

(71) Applicant: Bender GmbH & Co. KG, Gruenberg (DE)

(72) Inventors: Karl Schepp, Reiskirchen (DE); Dirk Gottwalles, Lollar (DE)

(21) Appl. No.: 14/593,338

(22) Filed: Jan. 9, 2015

(30) Foreign Application Priority Data
Jan. 10, 2014 (DE) 10 2014 200 288.5

(51) Int. Cl. G01R 31/12; G01R 31/02

(52) U.S. Cl. CPC G01R 31/1245; G01R 31/024

(57) ABSTRACT

A method for processing and displaying insulation resistance values in insulation fault monitoring devices for an IT power supply system includes determining an insulation resistance value in predetermined time intervals, detecting an insulation fault if the determined resistance value falls below a preset limit value, showing an optical alarm message if the insulation fault is present, wherein the determined insulation resistance value is time stamped and stored, the time stamp marked as the alarm time upon detection of the insulation fault, after determining and storing n insulation resistance values following the alarm time, a number n of the insulation resistance values determined prior to the alarm time, the insulation resistance value determined at the alarm time and a number n of the insulation resistance values determined after the alarm time are copied into a cache and graphically displayed. An insulation monitoring device for an IT power supply system is also described

This application claims the benefit of German national patent application 10 2014 200 288.5, the disclosure of which is incorporated herein by reference.

### TECHNICAL FIELD

The invention relates to a method for processing and displaying insulation resistance values in insulation fault monitoring devices for an IT power supply system, including the following method steps: determining an insulation resistance value in predetermined time intervals, detecting an insulation fault if the determined insulation resistance value falls below a preset limit value and showing an optical alarm message if the insulation fault is present.

Further, the invention relates to an insulation monitoring device for an IT power supply system, comprising a registration device for determining an insulation resistance value in predetermined time intervals and for detecting an insulation fault and comprising a reporting device for optically displaying an alarm if the insulation fault is present.

### BACKGROUND

For supplying electrical components, the network type of an IT system (isolated network) is used in case of increased demands on operation, fire and contact safety. In this type of power supply network, the active components of the installation are separated from the ground potential. The advantage of these networks lies in the fact that the function of the electrical components is not affected in case of a first insulation fault (ground fault or fault to frame) because no closed circuit can form in this first fault case owing to the ideally infinitely high impedance value between the conductor and ground.

It becomes clear from this consideration that the resistance against ground (insulation resistance—also fault resistance in the fault case) in the network to be monitored has to be monitored constantly because a potential second fault in another active conductor (second fault) would cause a fault loop and the flowing fault current, in connection with an overcurrent protection device, would result in a shutdown of the installation and in a standstill of operation.

According to standard DIN VDE 0100-410:2007-06, the use of an insulation monitoring system is required for the operation of such a network so that an alarm is reported in case of a first fault and the insulation fault can be located and resolved as quickly as possible before a second fault can cause a shutdown of the power supply system.

The requirements with regard to suitable insulation monitoring devices are laid out in international standard IEC 61557-8. According to said standard, the insulation monitoring device must be capable of monitoring the insulation resistance of the IT system including symmetrical and unsymmetrical components and of triggering an alarm message if the insulation resistance between the network and ground falls below a preset limit value (response value). The message is reported by means of a device that has to comprise an optical reporting device. The device must not be capable of being turned off and it has to signal the response.

The technical state of the art in the measuring technology of insulation monitoring devices, in particular with regard to measuring methods for determining the insulation resistance, is described in documents EP 1 586 910 B1, EP 0 654 673 B1 and DE 10 106 200 C1, for example. According to prior art, however, only the information that a response value has been undercut is available locally at the insulation monitoring device in case of an alarm message. An evaluation of the alarm message is possible only after further diagnoses, which require the time and cost-intensive deployment of service staff and cause a disruption or interruption of the operation of the installation to be monitored. For instance, drawn-out measurements by means of special measuring devices and long-term tests are often carried out only after the response of the insulation monitoring device in order to be able to comprehensively evaluate the state of the electrical installation or of the IT system with the aid of data loggers.

To be able to quickly initiate corresponding measures in an effective and economically reasonable manner, further information on the alarm message would be desirable, such as whether it is due to a transient ground fault, a creeping insulation fault, a distorted measurement with faulty response or the like.

### SUMMARY

Therefore, it is the object of the present invention to design a method for insulation monitoring devices and to enhance an insulation monitoring device to the effect that the operator of the installation can quickly, safely and cost-efficiently decide whether a true insulation fault is occurring.

With regard to a method, this object is attained in connection with the preamble of claim 1 in that the determined insulation resistance value is provided with a time stamp and stored, the time stamp belonging to the determined insulation resistance value is marked as the alarm time upon detection of the insulation fault, that after determining and storing n insulation resistance values following the alarm time, a number n of the insulation resistance values determined prior to the alarm time, the insulation resistance value determined at the alarm time and a number n of the insulation resistance values determined after the alarm time are copied into a cache and the insulation resistance values copied into the cache are graphically displayed.

Providing each determined insulation resistance value with a time stamp and storing them allows associating the insulation resistance values with a point in time. If the determined insulation resistance value falls below a preset limit value, the time stamp associated with this insulation resistance value is marked as the alarm time. After n further insulation resistance values following the alarm time have been recorded including a time stamp, the last recorded 2n+1 values are copied into a cache and are thus available for further evaluation. The data copied into the cache can then be graphically displayed in an alarm diagnosis display so as to help the user in assessing the fault case by optical diagnosis and thus allow a quick and secure assessment of the electrical state of the installation. The storing and graphic displaying offers the advantage of a quick performance of insulation fault location, which in turn leads to cost-saving by avoiding unnecessary service operations. Moreover, the alarm diagnosis display aids the fact that the measuring methods implemented in the insulation monitoring device and the implemented parameter settings can be optimized or that a more suitable insulation monitoring device has to be selected in view of a quick and secure assessment of the alarm message.

In a preferred embodiment, the insulation resistance values are graphically displayed as a function of time. Important conclusions regarding the past and present state of insulation of the electrical installation to be monitored can be drawn and predictions on future behavior can be made from the display of the temporal progression of the recorded insulation resistance values. In this way, at a glance, the user receives information on the development of the state of insulation of the network to be monitored in the temporal environment of the alarm time.

Advantageously, the insulation resistance values copied into the cache are subjected to digital signal processing. By methods of digital signal processing, the insulation resistance values can be prepared for graphic display in that their progression is smoothed by low-pass filtering, for example, so as to better recognize trends by eliminating high-frequency noise components or in that additional information for assessment of the fault case is offered by calculating statistical characteristics. The results of such an automated assessment of the curve progression can help the user in judging the reliability of the alarm message.

It proves convenient that results obtained by means of digital signal processing are graphically displayed by symbols or text characters. By displaying simple symbols, such as arrows for trend indication, bar charts or signal lights for conveying information on reliability, the informative value of the graphic display can be further increased with the objective of enabling the user to more easily assess the fault case.

Further, a raster width is automatically adapted to the predetermined time interval in graphic display. With this embodiment, a new insulation resistance value is registered and displayed per raster width so that the association between the insulation resistance value and the time stamp/time is instantly visible to the user.

Advantageously, the number n of the insulation resistance values that are stored prior to and after the alarm time is adjustable. A variable adjustment of the number of insulation resistance values to be stored and displayed allows adapting the diagnosis option to the electrical characteristics of the installation to be monitored and permits a compromise between short-term observation and long-term trend detection.

With regard to an insulation monitoring device, the object is attained in connection with the preamble of claim 7 in that the registration device comprises means for marking the determined insulation resistance value with a time stamp and is provided with a memory unit for storing the insulation resistance values provided with the time stamp, a cache into which a number n of the insulation resistance values determined prior to the alarm time, determined at the alarm time and a number n of the insulation resistance values determined after the alarm time are copied and an optical displaying device that graphically renders the insulation resistance values copied into the cache.

According to the invention, the insulation monitoring device comprises means for providing the determined insulation resistance values with a time stamp. Said means can be implemented as a processing unit in the form of a microprocessor in connection with a suitable software program and associate each determined insulation resistance value with the time stamp of its determination. The determined insulation resistance value is stored in a memory unit together with the associated time stamp. The insulation monitoring device further comprises a cache into which the past 2n+1 values are copied as soon as n further insulation resistance values have been determined since the occurrence of an insulation fault. An optical displaying device graphically renders the insulation resistance values stored in the cache. In an implementation of the method according to the invention, the means for marking the determined insulation resistance value with a time stamp, the memory unit for storing the insulation resistance values provided with the time stamp, the cache and the optical displaying device allow an alarm diagnosis that leads to a quick, reliable and cost-efficient assessment of the alarm situation.

Preferably, the displaying device is embodied as a display for rendering a temporal curve progression. The optical presentation of the cached data as a display of a curve progression on a screen, for example, offers the user the possibility of getting a quick overview of the temporal development of the insulation resistance.

Further, the insulation monitoring device comprises a digital signal processing unit for processing the insulation resistance values copied into the cache. The values of the insulation resistance stored in the cache are subjected to digital signal processing in view of an automated evaluation. Results of said digital signal processing can be a display of the temporal progression of the insulation values free of noise components or they can be statistical characteristics, for example.

For displaying the results obtained by means of digital signal processing, the displaying device comprises symbols or text characters. By simple symbols, the information obtained in an automated fashion can be conveyed quickly and clearly.

### BRIEF DESCRIPTION OF THE DRAWING FIGURES

Other advantageous embodiments become apparent from the following description and the drawings, which illustrate a preferred embodiment of the invention by way of examples. In the figures:

FIG. 1: shows a flow chart of the method according to the invention, and

FIGS. 2a to 2f: show temporal curve progressions of the insulation resistance value for different insulation-fault cases.

### DETAILED DESCRIPTION

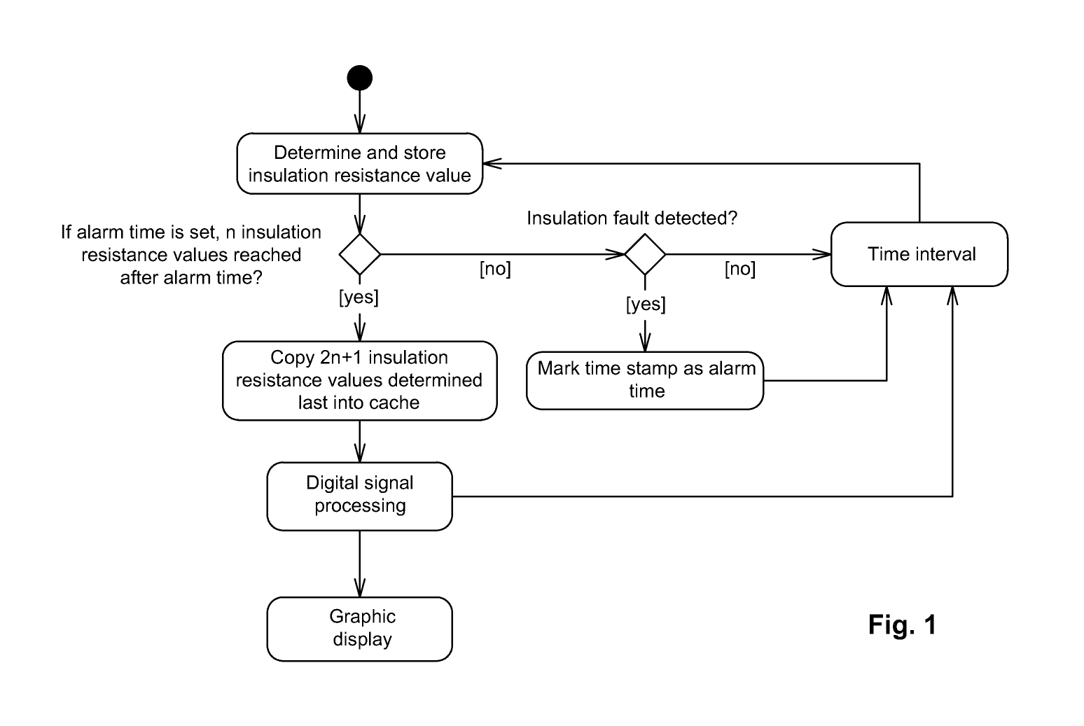

FIG. 1 represents the underlying method of the present invention in the form of a flow chart. Once the insulation monitoring device has been initiated, an insulation resistance value is determined in the registration device and stored in a memory unit together with a time stamp. As long as no insulation fault occurs, i.e. no time stamp is marked as an alarm time, further insulation resistance values are determined and stored in a loop in such a manner that, in a “steady state” of the insulation monitoring device, a frame of the last n+1 values is available at any time. If the insulation resistance value determined last is recognized as an insulation fault, the time stamp associated with this insulation resistance value is marked as an alarm time and n further insulation resistance values are determined and stored in the memory unit. As soon as 2n+1 data sets are available, they are copied into a cache and can be delivered to digital signal processing and then to a graphic display. The continuous monitoring of the current insulation resistance continues independently.

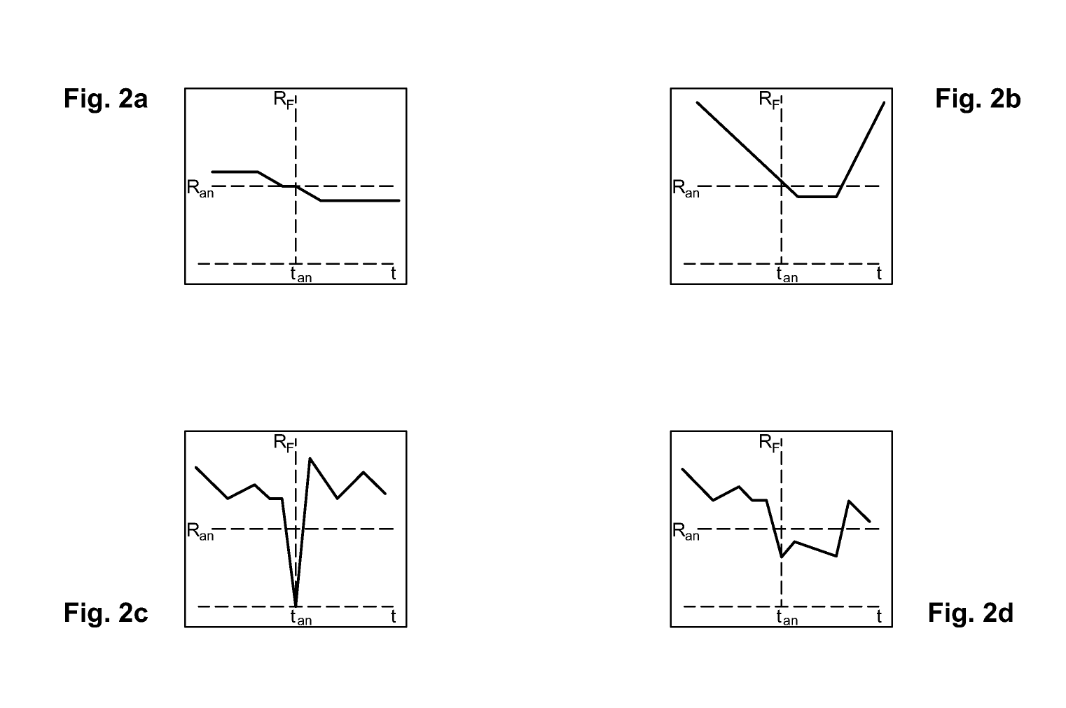

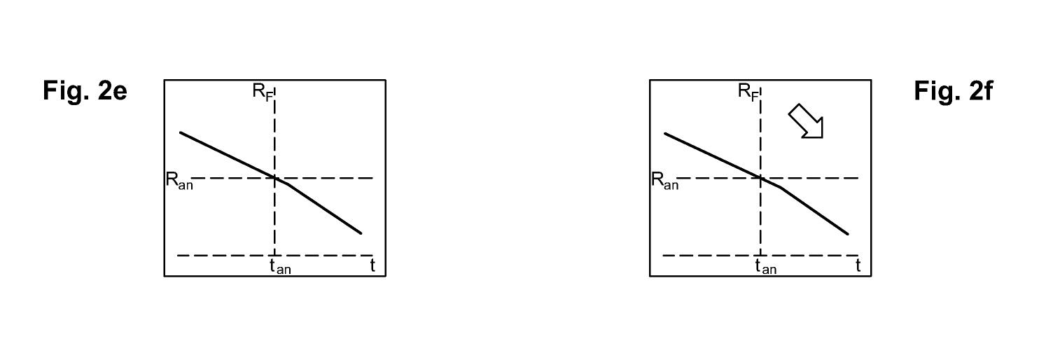

In FIGS. 2a to 2f, possible temporal curve progressions of the insulation resistance value are illustrated for different insulation fault causes. The determined insulation resistance value is plotted as a function of time, the additionally introduced lines representing the preset limit value (response value) with the associated alarm time as a time stamp.

In FIG. 2a, the insulation resistance value has slowly approached the response value. The measurement shows a stable progression and it can be assumed that the value of the insulation resistance will continue to slowly decrease.

FIG. 2b shows a ramp-shaped decrease of the insulation resistance value, the response value having been undercut for a duration of several measuring periods (time intervals). The measurement is stable, too, so that the occurrence of the insulation fault is dependent with high likelihood on the operating mode of the electrical installation.

In FIG. 2c, the determined insulation resistance value fluctuates heavily and the alarm threshold (response value) has been undercut for only a short time. The temporal progression thus suggests a false alarm.

FIG. 2d also shows a heavily fluctuating progression of the determined insulation resistance value. However, the alarm threshold was undercut at various differences for several measuring periods. The cause of the fault remains unclear.

FIG. 2e shows a very stable dropping progression of the determined insulation resistance value, which is very likely to continue in this manner.

In FIG. 2f, a symbol to indicate the trend assessment is illustrated in addition to the temporal progression of the insulation resistance value. The double arrow pointing downward to the right suggests an increasingly low-resistance insulation resistance value. Correspondingly, an increasingly high-resistance insulation resistance can be represented by an arrow pointing upwards to the right, a constant insulation resistance can be represented by a horizontal arrow and an insulation resistance tending to vary can be represented by a vertical double arrow.

1. A method for processing and displaying insulation resistance values in insulation fault monitoring devices for an IT power supply system, comprising the method steps:
determining an insulation resistance value in predetermined time intervals,
detecting an insulation fault, if the determined insulation resistance value falls below a preset limit value,
showing an optical alarm message if the insulation fault is present,
characterized in that
the determined insulation resistance value is provided with a time stamp and stored,
the time stamp belonging to the determined insulation resistance value is marked as the alarm time upon detection of the insulation fault,
after n insulation resistance values following the alarm time are determined and stored, a number n of the insulation resistance values determined prior to the alarm time, the insulation resistance value determined at the alarm time and a number n of the insulation resistance values determined after the alarm time are copied into a cache,
the insulation resistance values copied into the cache are graphically displayed.

2. The method according to claim 1,
characterized in that
the insulation resistance values are graphically displayed as a function of time.

3. The method according to claim 1,
characterized in that
the insulation resistance values that were copied into the cache are subjected to digital signal processing.

4. The method according to claim 3,
characterized in that
the results obtained by means of the digital signal processing are graphically displayed by symbols or text characters.

5. The method according to claim 1,
characterized in that
in the graphic display, a raster width is automatically adapted to the predetermined time interval.

6. The method according to claim 1,
characterized in that
the number n of the insulation resistance values stored prior to and after the alarm time can be adjusted.

7. An insulation monitoring device for an IT power supply system,
comprising a registration device for determining an insulation resistance value in predetermined time intervals and for detecting an insulation fault and comprising a reporting device for optically displaying an alarm if the insulation fault is present,
characterized in that
the registration device comprises means for marking the determined insulation resistance value with a time stamp and is provided with a memory unit for storing the insulation resistance values provided with the time stamp, with a cache into which a number n of the insulation resistance values determined prior to the alarm time, determined at the alarm time and a number n of the insulation resistance values determined after the alarm time are copied and with an optical displaying device that graphically renders the insulation resistance values copied into the cache.

8. The device according to claim 7,
characterized in that
the displaying device is embodied as a display for rendering a temporal curve progression.

9. The device according to claim 7,
characterized by
a digital signal processing unit for processing the insulation resistance values copied into the cache.

10. The device according to claim 7,
characterized in that
the displaying device comprises symbols or text characters for rendering the results obtained by means of the digital signal processing.
